(19) United States
(12) Patent Application Publication
(10) Pub. No.: US 2024/0251608 A1
(43) Pub. Date: Jul. 25, 2024

(54) FLEXIBLE DISPLAY SUBSTRATE, DISPLAY PANEL, AND DISPLAY DEVICE

(71) Applicant: BOE Technology Group Co., Ltd., Beijing (CN)

(72) Inventors: Xuliang ZHAO, Beijing (CN); Hao ZHANG, Beijing (CN); Jia ZHAO, Beijing (CN); Xiyu ZHAO, Beijing (CN); Pinfan WANG, Beijing (CN)

(73) Assignee: BOE Technology Group Co., Ltd., Beijing (CN)

(21) Appl. No.: 18/289,575

(22) PCT Filed: Jan. 4, 2023
(86) PCT No.: PCT/CN2023/070264

§ 371 Date: Nov. 6, 2023

(30) Foreign Application Priority Data
Feb. 25, 2022 (CN) 202210179605.6

(51) Int. Cl. H10K 59/124; H10K 59/80; H10K 102/00

(52) U.S. Cl. CPC H10K 59/124; H10K 59/873; H10K 2102/311

(57) ABSTRACT

Provided is a flexible display substrate, including: a peripheral region and a display region. The peripheral region surrounds the display region. The peripheral region has a plurality of corner regions, and at least one of the corner regions includes two first regions and a second region disposed between the two first regions. The first region has a hollow structure, and the second region has at least one notch disposed in an edge of the flexible display substrate.

### CROSS-REFERENCE TO RELATED APPLICATIONS

This application is a U.S. national stage of International Application No. PCT/CN2023/070264, filed on Jan. 4, 2023, which claims priority to Chinese Patent Application No. 202210179605.6, filed on Feb. 25, 2022 and entitled “FLEXIBLE DISPLAY SUBSTRATE, DISPLAY PANEL, AND DISPLAY DEVICE,” the contents of each are incorporated herein by reference in their entireties.

### TECHNICAL FIELD

The present disclosure relates to the field of display devices, and in particular relates to a flexible display substrate, a display panel, and a display device.

### BACKGROUND

With the development of display technologies, flexible display technologies are maturing, and in addition to bendable and foldable display substrates, stretchable display substrates are also maturing.

### SUMMARY

Embodiments of the present disclosure provide a flexible display substrate, a display panel, and a display device. The technical solutions are described as below.

According to some embodiments of the present disclosure, a flexible display substrate is provided. The display substrate includes a peripheral region and a display region, the peripheral region surrounding the display region; wherein the peripheral region has a plurality of corner regions, at least one of the corner regions including two first regions and a second region disposed between the two first regions; and the first region has a hollow structure, and the second region has at least one notch disposed in an edge of the flexible display substrate.

In some embodiments, the notch is a semi-elliptical notch, a semi-circular notch, a rectangular notch, a trapezoidal notch, or an arcuate notch.

In some embodiments, a long axis of the notch is intersected with an edge, in which the notch is disposed, at one intersection point.

For shapes such as ellipses and semi-ellipses, the long axis is the longest axis of the ellipse or semi-ellipse. For other symmetrical shapes such as rectangles, the long axis is the axis of symmetry with the greatest length. For asymmetric shapes, the long axis is the longest line segment that runs through the center of the shape with both endpoints at the edges of the shape.

In some embodiments, the notch is the semi-elliptical notch.

In some embodiments, a long axis of the semi-elliptical notch ranges from 200 μm to 600 μm.

In some embodiments, a short axis of the semi-elliptical notch ranges from 40 μm to 80 μm; and in the case that the second region has a plurality of the semi-elliptical notches, a minimum distance between adjacent two of the semi-elliptical notches ranges from 5 μm to 40 μm.

In some embodiments, the second region includes: two first sub-regions and one second sub-region, wherein the second sub-region is disposed between the two first sub-regions, the first sub-region and the second sub-region are arranged in an extension direction along the edge of the flexible display substrate, and the notch is disposed in each of the two first sub-regions.

In some embodiments, the second sub-region is disposed in a center of the corner region. In some embodiments, the second sub-region is a non-hollow region.

In some embodiments, the flexible display substrate further includes a peripheral circuit, wherein at least a portion of the peripheral circuit is disposed within the second region.

In some embodiments, the peripheral circuit includes a GOA circuit, wherein the GOA circuit is disposed in the second sub-region.

In some embodiments, the hollow structure includes a plurality of I-shaped holes, the plurality of I-shaped holes including at least one of a first through-hole and a second through-hole; wherein the first through-hole includes a first strip-shaped body portion and two trapezoidal portions, wherein the two trapezoidal portions are respectively disposed at both ends of the first strip-shaped body portion and an upper base of the trapezoidal portion is connected to the first strip-shaped body portion; and the second through-hole includes a second strip-shaped body portion and two strip-shaped branch portions, wherein the two strip-shaped branch portions are respectively disposed at both ends of the second strip-shaped body portion and a middle of each of the two strip-shaped branch portions is connected to the second strip-shaped body portion.

In some embodiments, a length of the first strip-shaped body portion or the second strip-shaped body portion ranges from 170 μm to 600 μm; a length of the trapezoidal portion or the strip-shaped branch portion ranges from 60 μm to 160 μm; widths of the first strip-shaped body portion and the trapezoidal portion or the second strip-shaped body portion and each of the two strip-shaped branch portions both range from 4 μm to 50 μm; and a minimum distance between adjacent two of the I-shaped holes ranges from 80 μm to 200 μm.

In some embodiments, a gap between adjacent two of the I-shaped holes is a bridge region and a gap enclosed by adjacent four of the I-shaped holes is an island region; wherein wirings are arranged in the bridge region and peripheral circuits are arranged in the island region.

In some embodiments, the display region has the hollow structure, and an area of the hollow structure disposed in the display region per unit area is greater than an area of the hollow structure disposed in the peripheral region.

In some embodiments, the hollow structure of the display region includes the plurality of I-shaped holes, and the plurality of I-shaped holes include at least one of the first through-hole and the second through-hole; the first through-hole includes the first strip-shaped body portion and the two trapezoidal portions, the two trapezoidal portions are respectively disposed at the two ends of the first strip-shaped body portion, and an upper base of the trapezoidal portion is connected to the first strip-shaped body portion; and the second through-hole includes the second strip-shaped body portion and the two strip-shaped branch portions, the two strip-shaped branch portions are respectively disposed at the two ends of the second strip-shaped body portion, and the middle of each of the two strip-shaped branch portions is connected to the second strip-shaped body portion.

In some embodiments, the length of the first strip-shaped body portion or the second strip-shaped body portion disposed in the display region is greater than the length of the first strip-shaped body portion or the second strip-shaped body portion disposed in the peripheral region.

In some embodiments, the length of the first strip-shaped body portion or the second strip-shaped body portion disposed in the display region ranges from 250 μm to 800 μm; the length of the trapezoidal portion or the strip-shaped branch portion ranges from 100 μm to 250 μm; the widths of the first strip-shaped body portion and the trapezoidal portion or the second strip-shaped body portion and each of the two strip-shaped branch portions both range from 4 μm to 50 μm; and the minimum distance between the adjacent two of the I-shaped holes ranges from 40 μm to 100 μm.

In some embodiments, the bridge region and the island region are disposed between the I-shaped holes disposed in the display region; wherein an area of the island region disposed in the display region is less than an area of the island region disposed in the peripheral region, and a width of the bridge region disposed in the display region is less than a width of the bridge region disposed in the peripheral region.

In some embodiments, the flexible display substrate includes: a flexible substrate, and a display functional film layer and a cover plate that are sequentially disposed on the flexible substrate, wherein a projection of edges of the flexible substrate and the cover plate in a plane that a surface of the display functional film layer is within is outside a surface of the display functional film layer.

According to some embodiments of the present disclosure, a display panel is provided. The display panel includes the flexible display substrate as described in any one of the first aspect.

According to some embodiments of the present disclosure, a display device is provided. The display device includes the display panel as described in the second aspect.

### BRIEF DESCRIPTION OF DRAWINGS

For clearer descriptions of the technical solutions in the embodiments of the present disclosure, the following briefly introduces the accompanying drawings required for describing the embodiments. Apparently, the accompanying drawings in the following description illustrate merely some embodiments of the present disclosure, and persons of ordinary skill in the art may still derive other drawings from these accompanying drawings without creative efforts.

FIG. 1 is a schematic diagram of a region of a flexible display substrate according to some embodiments of the present disclosure;

FIG. 2 is a schematic structure diagram of a flexible display substrate according to some embodiments of the present disclosure;

FIG. 3 is a schematic diagram of a distribution of strain regions in a corner region according to some embodiments of the present disclosure;

FIG. 4 is a schematic diagram of a force applied to a corner region of a flexible display substrate according to some embodiments of the present disclosure;

FIG. 5 is a schematic diagram of a peripheral circuit arrangement according to some embodiments of the present disclosure;

FIG. 6 is a schematic diagram of dimensioning of a semi-elliptical notch according to some embodiments of the present disclosure;

FIG. 7 is a schematic structure diagram of a first through-hole according to some embodiments of the present disclosure;

FIG. 8 is a schematic structure diagram of a second through-hole according to some embodiments of the present disclosure;

FIG. 9 is a schematic diagram of dimensioning of a hollow structure according to some embodiments of the present disclosure;

FIG. 10 is a schematic structure diagram of an I-shaped hole according to some embodiments of the present disclosure;

FIG. 11 is a schematic structure diagram of a flexible display panel according to some embodiments of the present disclosure;

FIG. 12 is a schematic structure diagram of a flexible display panel according to some embodiments of the present disclosure;

FIG. 13 is a schematic diagram of dimensioning of a strip-shaped hole according to some embodiments of the present disclosure;

FIG. 14 is a schematic diagram of layers of a flexible display substrate according to some embodiments of the present disclosure; and

FIG. 15 is a flowchart of a method for manufacturing a flexible display substrate according to some embodiments of the present disclosure.

### DETAILED DESCRIPTION

To make the objectives, technical solutions, and advantages of the present disclosure clearer, the following further describes implementations of the present disclosure in detail with reference to the accompanying drawings.

Unless otherwise defined, technical or scientific terms used herein shall have their ordinary meaning as understood by a person of ordinary skill in the art to which this disclosure pertains. The terms “first,” “second,” “third,” and the like, as used in the specification of the patent disclosure and the claims of the present disclosure, do not denote any order, number, or significance, but are used only to distinguish between different components. Similarly, the term “a” or “an” and similar terms do not indicate a limitation of quantity, but rather the existence of at least one. Similar terms such as “includes” or “contains” mean that the element or object that now precedes “includes” or “contains” encompasses the elements or objects listed after “includes” or “contains” and their equivalents, and does not exclude other elements or objects. The terms such as “connected” or “coupled” are not limited to physical or mechanical connections, but may include electrical connections, whether direct or indirect. The terms “up,” “down,” “left,” “right,” and the like are used only to indicate relative positional relationships. When the absolute position of the described object is changed, the described relative positional relations may be changed accordingly.

A stretchable flexible display substrate has a hollow structure which is disposed in a peripheral region of the flexible display substrate. When the flexible display substrate is subjected to stretching, the peripheral region is capable of generating a tensile deformation, for example, causing the peripheral region to be attached onto the bezel of the mounted terminal by stretching to realize curved-screen design.

However, for four corners of the flexible display substrate, a total stretching amount on two adjacent sides of the flexible display substrate in the stretching process causes corrugations at the corners due to extrusion, which affects the attachment effect.

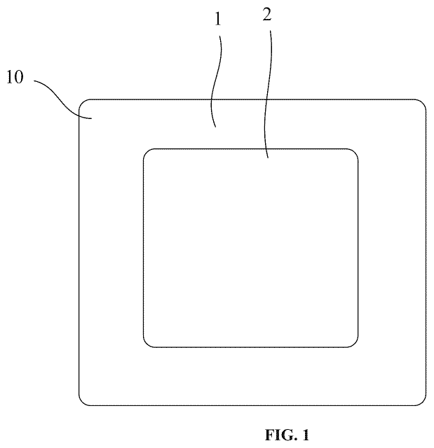

FIG. 1 is a schematic diagram of a region of a flexible display substrate according to some embodiments of the present disclosure. Referring to FIG. 1, the flexible display substrate includes a peripheral region 1 and a display region 2, wherein the peripheral region 1 surrounds the display region 2.

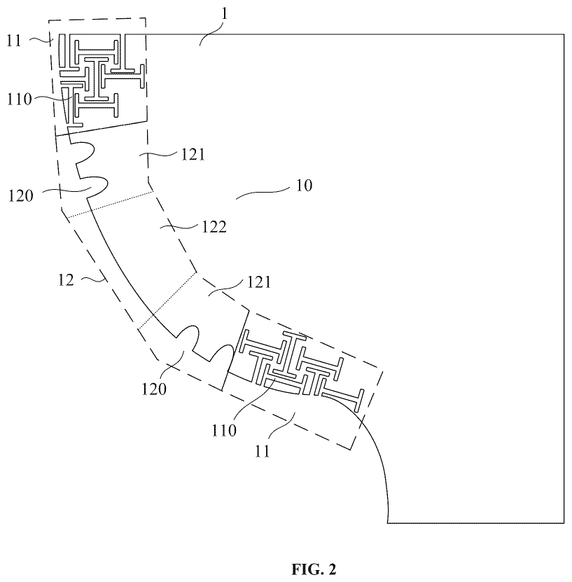

FIG. 2 is a schematic partial structure diagram of a portion of a flexible display substrate according to some embodiments of the present disclosure. As illustrated in FIG. 2, a peripheral region 1 has a plurality of corner regions 10 (only one of which is illustrated in FIG. 2), that is, a rectangular flexible display substrate has four corner regions. The rectangular flexible display substrate is a right-angled flexible display substrate or a rounded flexible display substrate, which is not limited by the embodiments of the present disclosure. The corner region 10 is a region including corners, for example, a rectangular region with a corner as a corner, or a sector-shaped region with a corner as an arc, and the embodiments of the present disclosure do not limit the shape of the corner region 10 either.

At least one corner region 10 includes two first regions 11 and a second region 12 disposed between the two first regions 11; and the first region 11 has a hollow structure 110, wherein the hollow structure causes a tensile deformation of the flexible display substrate when subjected to stretching, facilitating the attachment of the flexible display substrate. The second region 12 has at least one notch 120 disposed in the edge of the flexible display substrate, the notch being configured to absorb the compression deformation in the corner region of the flexible display substrate and mitigate the corrugations generated by the compression deformation.

Exemplarily, each corner region 10 in the flexible display substrate is provided in accordance with the structure described above.

In the embodiments of the present disclosure, by providing a notch in the edge of the second region in the middle of the corner region of the peripheral region of the flexible display substrate, when the peripheral region of the flexible display substrate is downwardly stretched to be attached to the bezel of the terminal to be mounted, the notch is able to absorb shrinkage deformation during attachment, and deformation amounts in the corner region are counteracted by the notch, thereby addressing the problem of causing corrugations during attachment in the corner region and improving the attachment effect.

In addition, the attaching method makes the attachment depth of the peripheral region deeper, thereby making the display region of the display surface of the display panel account for a larger proportion of the display region, which is conducive to improving the screen-to-body ratio.

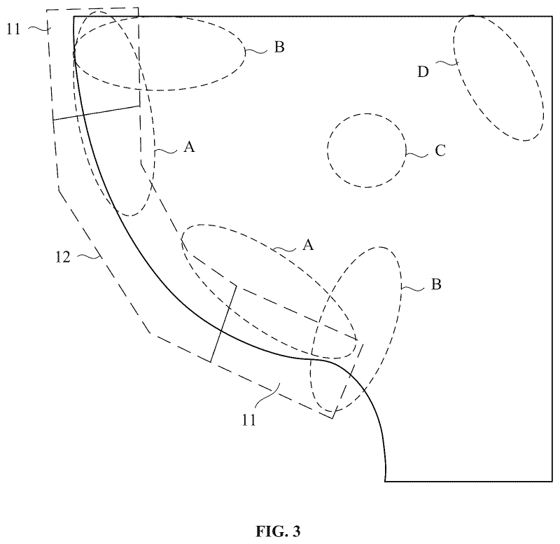

FIG. 3 is a schematic diagram of a distribution of strain regions in a corner region according to some embodiments of the present disclosure. Referring to FIG. 3, the strain regions in the corner region include: two compressive strain maximum regions A and two tensile strain maximum regions B.

As illustrated in FIG. 3, the tensile strain maximum region B and the compressive strain maximum region A are overlapped in the aforementioned first region 11, while in the second region 12, both sides belong to the compressive strain maximum region A, and the middle is an unstressed region.

It is to be noted that the flexible display substrate also has a tensile strain minimal region C and a compressive strain minimal region D, both of which are typically disposed in the display region of the flexible display substrate.

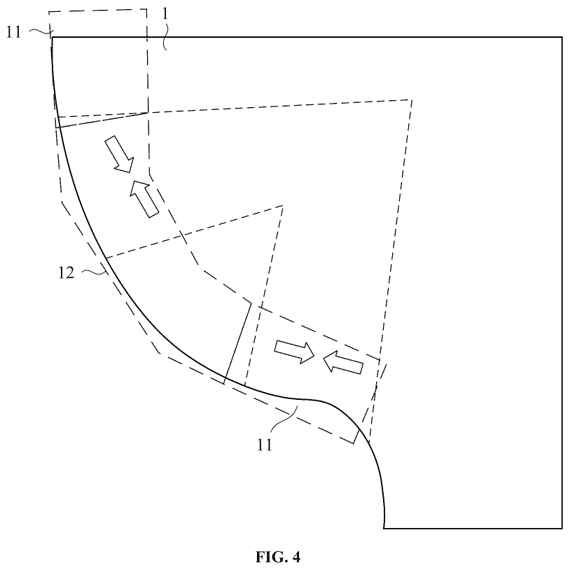

FIG. 4 is a schematic diagram of a force applied to a corner region of a flexible display substrate according to some embodiments of the present disclosure. Referring to FIG. 4, due to the strain region distribution described above, both sides of a second region 12 are subjected to a large squeezing force (as illustrated by the arrows in FIG. 4), which in turn leads to corrugations in the region. The present disclosure improves the attachment effect by arranging a notch 120 in the second region, such that the corrugations are offset.

Referring to FIG. 2 again, the second region 12 includes: two first sub-regions 121 and one second sub-region 122, wherein the second sub-region 122 is disposed between the two first sub-regions 121, the first sub-regions 121 and the second sub-regions 122 are arranged in an extension direction along an edge of the flexible display substrate, and the notch 120 is disposed in each of the two first sub-regions 121.

Exemplarily, the second sub-region 122 is disposed in the center of the corner region 10.

Herein, the second sub-region 122 is the aforementioned unstressed region, and the first sub-region 121 is the compressive strain maximum region, i.e., the region subjected to a large squeezing force in FIG. 4. Thus, disposing the notch 120 in the first sub-region 121 alleviates, or even eliminates, the corrugations.

Since the second sub-region 122 is the unstressed region, the second sub-region 122 is the non-hollow region, that is, neither the notch nor the hollow structure is disposed in the second sub-region 122.

Since the second sub-region 122 is neither provided with the notch nor the hollow structure, a circuit structure is provided in the second sub-region 122.

FIG. 5 is a schematic diagram of a peripheral circuit arrangement according to some embodiments of the present disclosure. Referring to FIG. 5, the flexible display substrate further includes a peripheral circuit 1220, wherein at least a portion of the peripheral circuit 1220 is disposed in the second region 12. Since the hollow structure 110 and the notch 120 in the peripheral region 1 result in decrease of the space originally for arranging the peripheral circuit, at least a portion of the peripheral circuit 1220 is provided in the second region 12, which alleviates the decreased space for arranging the peripheral circuit.

Exemplarily, the peripheral circuit 1220 includes Gate of Array (GOA) circuit, wherein the GOA circuit is disposed in the second sub-region 122.

In the flexible display substrate illustrated in FIG. 2, the notch 120 is a semi-elliptical notch.

In other possible implementations, the notch 120 is of other shapes. For example, the notch 120 is a semicircular notch, a rectangular notch, a trapezoidal notch, or an arcuate notch.

In the flexible display substrate illustrated in FIG. 2, a long axis of the semi-elliptical notch is intersected with an edge where the notch 120 is disposed at one intersection point. The semi-elliptical notch well mitigates the corrugations, and is arranged in a such manner that the long axis of the semi-elliptical notch is intersected with the edge where the notch 120 is disposed, it is possible to arrange a greater number of semi-elliptical notches in the first sub-region 121, which further improves the effect of mitigating the corrugations.

Exemplarily, the long axis of the semi-elliptical notch is perpendicular to the edge where the notch 120 is disposed. For example, for a right-angled rectangular flexible display substrate, the long axis of the semi-elliptical notch is perpendicular to the edge in which the notch 120 is disposed, and for a rounded rectangular flexible display substrate, the long axis of the semi-elliptical notch is perpendicular to a tangent to the edge in which the notch 120 is disposed.

In other embodiments, it is also possible that a short axis of the semi-elliptical notch is intersected with the edge in which the notch 120 is disposed, without limitation thereon.

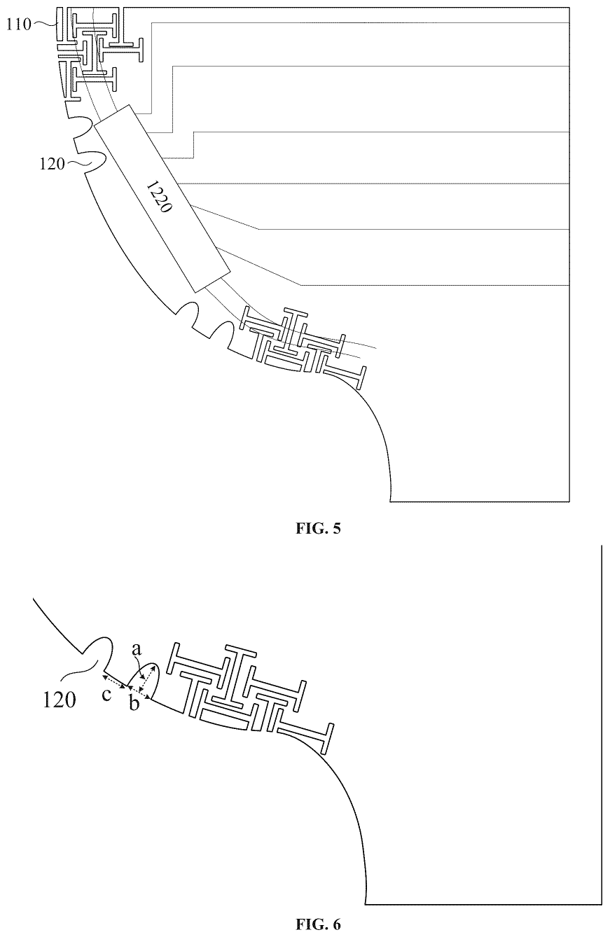

FIG. 6 is a schematic diagram of dimensioning of a semi-elliptical notch according to some embodiments of the present disclosure. Referring to FIG. 6, a long axis 2a of the semi-elliptical notch (a illustrated in FIG. 6 is half of the long axis) ranges from 200 μm to 600 μm, a short axis b of the semi-elliptical notch ranges from 40 μm to 80 μm, and in the case that a plurality of notches are provided, a minimum distance c between adjacent semi-elliptical notches ranges from 5 μm to 40 μm. It is to be noted that, for ease of observation, the distances between adjacent notches are not illustrated to scale in FIG. 6.

It is to be noted that the adjacent semi-elliptical notches typically refer to adjacent semi-elliptical notches in the same first sub-region 121.

Exemplarily, the long axis 2a of the semi-elliptical notch is 400 μm, the short axis b of the semi-elliptical notch is 60 μm, and the minimum distance c between adjacent semi-elliptical notches is 25 μm.

As illustrated in FIG. 2, the hollow structure 110 includes a plurality of I-shaped holes. The structure of the I-shaped hole is briefly described below in conjunction with the accompanying drawings.

The structure of the I-shaped holes is of two forms, a first through-hole and a second through-hole.

FIG. 7 is a schematic structure diagram of a first through-hole according to some embodiments of the present disclosure. Referring to FIG. 7, the first through-hole 111 includes a first strip-shaped body portion 1111 and two trapezoidal portions 1112, wherein the two trapezoidal portions 1112 are respectively disposed at both ends of the first strip-shaped body portion 1111, and upper bases of the trapezoidal portions 1112 are connected to the first strip-shaped body portion 1111.

Exemplarily, the trapezoidal portion 212 is an isosceles trapezoid, and the upper base of the trapezoidal portion 212 coincides with a width side of the first strip-shaped body portion 1111.

The trapezoidal portion 212 is disposed as an isosceles trapezoid, and the upper base of the trapezoidal portion 212 coincides with a side of the first strip-shaped body portion 1111, such that the first through-hole 21 is not only axially symmetric, but also centrally symmetric, which facilitates the neat arrangement of the first through-holes 21 in the flexible display substrate.

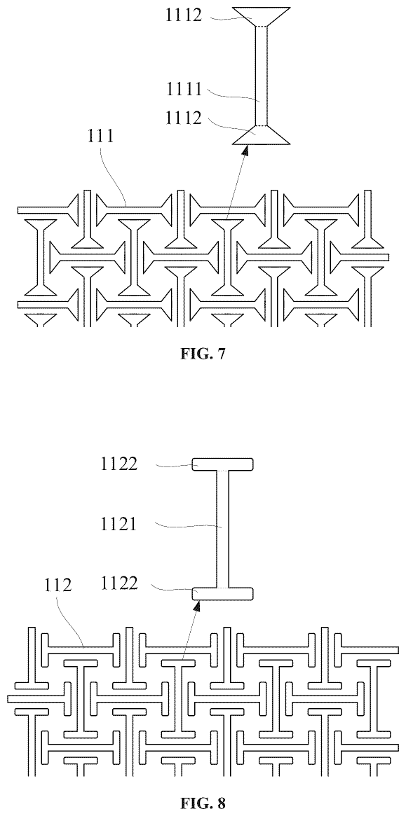

FIG. 8 is a schematic structure diagram of a second through-hole according to some embodiments of the present disclosure. Referring to FIG. 8, the second through-hole 112 includes a second strip-shaped body portion 1121 and two strip-shaped branch portions 1122, wherein the two strip-shaped branch portions 1122 are disposed at both ends of the second strip-shaped body portion 1121, and a middle of each of the two strip-shaped branch portions 1122 is connected to the second strip-shaped body portion 1121.

The second through-hole 112 differs from the first through-hole 111 in that the through-hole ends have different shapes.

As illustrated in FIG. 8, a length direction of the strip-shaped branch portion 1122 is perpendicular to a length direction of the second strip-shaped body portion 1121, and the strip-shaped branch portion 1122 is symmetrical with respect to the second strip-shaped body portion 1121.

Arranging the strip-shaped branch portion 1122 perpendicularly to the second strip-shaped body portion 1121 and making the strip-shaped branch portion 1122 symmetrical with respect to the second strip-shaped body portion 1121 also serves to make the second through-hole 112 not only axially symmetrical but also centrally symmetrical, and facilitate the neat arrangement of the second through-holes 112 in the flexible display substrate.

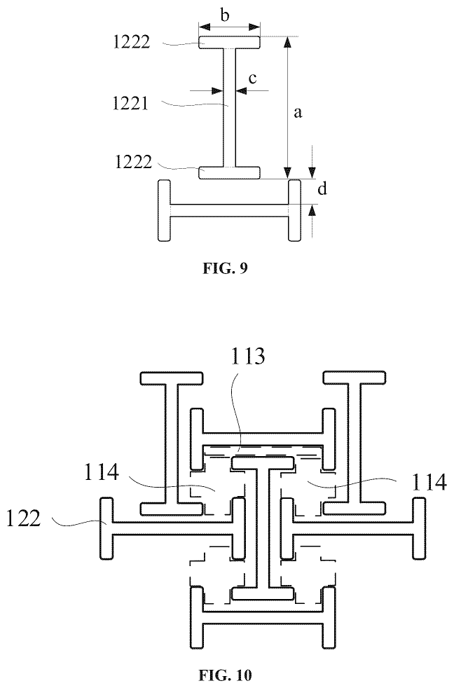

FIG. 9 is a schematic diagram of dimensioning of a hollow structure according to some embodiments of the present disclosure. Referring to FIG. 9, taking a second through-hole as an example for illustration, a length a of a second strip-shaped body portion 1121 ranges from 170 μm to 600 μm, a length b of a strip-shaped branch portion 1122 ranges from 60 μm to 160 μm, widths c of the second strip-shaped body portion 1121 and the strip-shaped branch portion 1122 range from 4 μm to 50 μm, and a minimum distance d between adjacent I-shaped holes ranges from 80 μm to 200 μm.

Exemplarily, the length a of the second strip-shaped body portion 1121 is 400 μm, the length b of the strip-shaped branch portion 1122 is 100 μm, and the width c of the second strip-shaped body portion 1121 and the strip-shaped branch portion is 30 μm, and the minimum distance d between adjacent I-shaped holes is 150 μm.

In the case that the hollow structure includes a first through-hole, a size of the first through-hole is the same as that of the second through-hole.

That is, a length of the first strip-shaped body portion 1111 ranges from 170 μm to 600 μm, a length of the trapezoid portion 1112 (i.e., a length of the bottom of the trapezoid portion) ranges from 60 μm to 160 μm, a width of the first strip-shaped body portion 1111 and the trapezoid portion 1112 (wherein the width of the trapezoid portion is also a height of the trapezoid portion) ranges from 4 μm to 50 μm, and the minimum distance between adjacent I-shaped holes ranges from 80 μm to 200 μm.

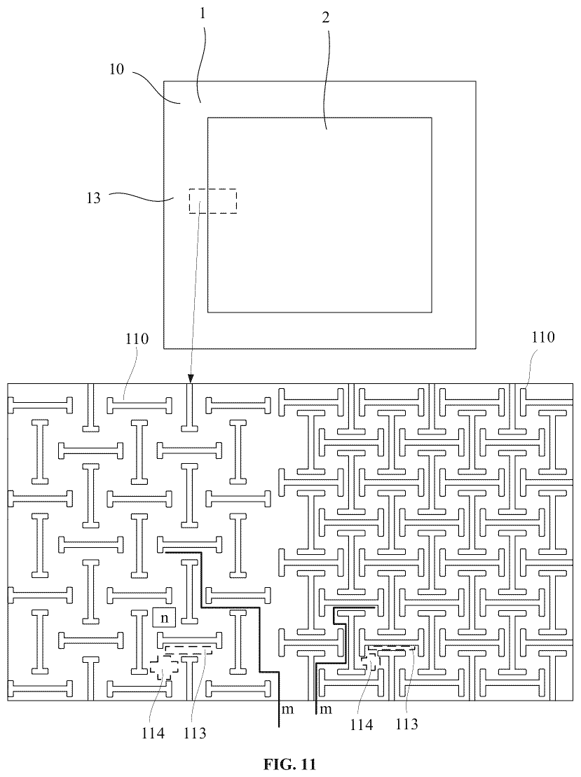

FIG. 10 is a schematic structure diagram of an I-shaped hole according to some embodiments of the present disclosure. Referring to FIG. 10, a gap between two adjacent I-shaped holes is a bridge region 113, and a gap enclosed by four adjacent I-shaped holes is an island region 114.

As illustrated in FIG. 10, a plurality of island regions 114 are disposed in an array, adjacent island regions 114 are connected by the bridge region 113, each island region 114 is connected to four bridge regions 113, the four bridge regions 113 are connected to different sides of the island region 114, and a connection of the bridge region 113 and the island region 114 is disposed at an end of the side.

In the embodiments of the present disclosure, a wiring is arranged in the bridge region 113.

Exemplarily, the power line (VDD) and the common voltage line (VSS) are only arranged in the bridge region, and the GOA wiring is arranged in a region where the hollow structure is not provided.

A width of the bridge region 113, i.e., the minimum distance d between the adjacent I-shaped holes, ranges from 80 μm to 200 μm. The width of the wiring is also in the order of tens of μm, such that the width of the bridge region 113 satisfies the wiring requirement.

In addition to arranging the peripheral circuit in the aforementioned second sub-region 112, the peripheral circuit is also arranged within the island region 114, thereby ensuring that a sufficient space is provided for the peripheral circuit.

In this case, the bridge region is simultaneously arranged with the VDD, the VSS and the GOA wirings.

The size of the island region 114 arranged according to the above size is 200 μm×200 μm, and a cell size of GOA circuit is 100 μm×150 μm, and therefore, the island region design meets the arrangement requirement of the GOA circuit.

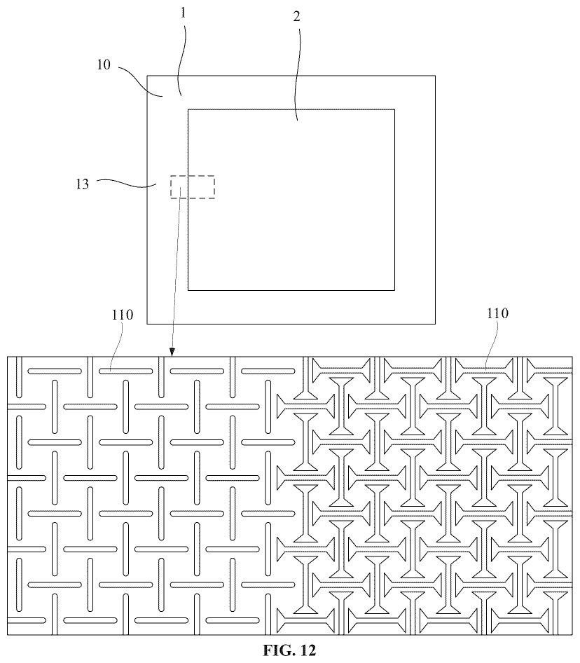

FIG. 11 is a schematic structure diagram of a flexible display panel according to some embodiments of the present disclosure. Referring to FIG. 11, a peripheral region 1 includes, in addition to a corner region 10, a central region 13 disposed between adjacent corner regions 10, wherein the central region 13 is provided with a hollow structure 110.

The hollow structure 110 in the central region 13 and the hollow structure 110 in the corner region 10 are the same or different.

For example, the hollow structure 110 in the central region 13 and the hollow structure 110 in the corner region 10 both include the I-shaped holes, wherein the I-shaped holes have the same shape and size.

For another example, the hollow structure 110 in the central region 13 and the hollow structure 110 in the corner region 10 include through-holes of different shapes, or of the same shape but different sizes, which is not described herein again.

It is to be noted that in the peripheral region, the hollow structure 110 is formed by the I-shaped holes, but also by the strip-shaped holes, or by a combination of the I-shaped and the strip-shaped holes.

In the embodiments of the present disclosure, a plurality of turns of I-shaped holes, such as 5 turns, are included in the peripheral region, which is not limited in the embodiments of the present disclosure. In the plurality of turns of I-shaped holes, the arrangements of the I-shaped holes in two adjacent turns are in different directions, for example in the directions that are perpendicular to each other.

Referring to FIG. 11 again, the display region 2 has the hollow structure 110. Within a unit area, an area of the hollow structure 110 in the display region 2 is greater than an area of the hollow structure 110 in the peripheral region 1.

The area of the hollow structure 110 refers to the area enclosed by the inner wall of the hollow structure 110 in the surface of the flexible display substrate in the case that the flexible display substrate is in a flattened and undeformed state.

That is, the area of the hollow structure in the peripheral region 1 is less, such that the peripheral region has a more sufficient space for arranging the peripheral circuit and the wiring. For example, in FIG. 11, a wiring m and a peripheral circuit n are arranged in the gap of the hollow structure in the peripheral region 1; the four corners are designed with a larger curvature to increase the depth of attachment, thereby hiding the peripheral region on the side and achieving the effect of full-screen display.

As illustrated in FIG. 11, the wiring m is also arranged in the gap of the hollow structure at the edge of the display region 1, which is not described herein.

In the embodiments of the present disclosure, the hollow structure 110 in the display region 2 includes a plurality of I-shaped holes, wherein the plurality of I-shaped holes include one of the first through-hole 111 and the second through-hole 112.

The first through-hole 111 includes the first strip-shaped body portion 1111 and two trapezoidal portions 1112. The two trapezoidal portions 1112 are respectively disposed at both ends of the first strip-shaped body portion 1111, and an upper base of the trapezoidal portion 1112 is connected to the first strip-shaped body portion 1111.

The second through-hole 112 includes the second strip-shaped body portion 1121 and two strip-shaped branch portions 1122. The two strip-shaped branch portions 1122 are respectively disposed at both ends of the second strip-shaped body portion 1121. A middle of each of the two strip-shaped branch portions 1122 is connected to the second strip-shaped body portion 1121.

In the embodiments of the present disclosure, the hollow structure 110 in the display region 2 and the hollow structure in the peripheral region 1 are the same or different.

For example, the hollow structure 110 in the display region 2 and the hollow structure 110 in the corner region 10 both include the I-shaped holes, or the hollow structure 110 in the display region 2 and the hollow structure 110 in the central region 13 both include the I-shaped holes, wherein the I-shaped holes have the same shape and size.

For another example, the hollow structure 110 in the display region 2, the hollow structure 110 in the corner region 10, and the hollow structure 110 in the central region 13 include through-holes that have different shapes, or have the same shape but different sizes.

Referring to FIG. 11, the through-holes included in the hollow structure 110 in the display region 2 and the peripheral region 1 are all I-shaped holes, but the sizes of the I-shaped holes are different, for example, the strip-shaped branch portion of the I-shaped holes in the display region 2 is greater, and the spacing between adjacent I-shaped holes in the peripheral region 1 is greater, such that the area of the hollow structure 110 in the display region 2 is greater than that of the hollow structure 110 in the peripheral region 1 per unit area.

That is, the length of the first strip-shaped body portion 1111 or the second strip-shaped body portion 1121 disposed in the display region 2 is greater than that of the first strip-shaped body portion 1111 or the second strip-shaped body portion 1121 disposed in the peripheral region 1.

Referring to FIG. 12, a through-hole in a hollow structure 110 in a display region 2 is an I-shaped hole, and a through-hole in the hollow structure 110 in a peripheral region 1 is a strip-shaped hole, both of which have different shapes.

Using the strip-shaped hole in the peripheral region 1 allows more space in the peripheral region for arranging the peripheral circuits and the wirings.

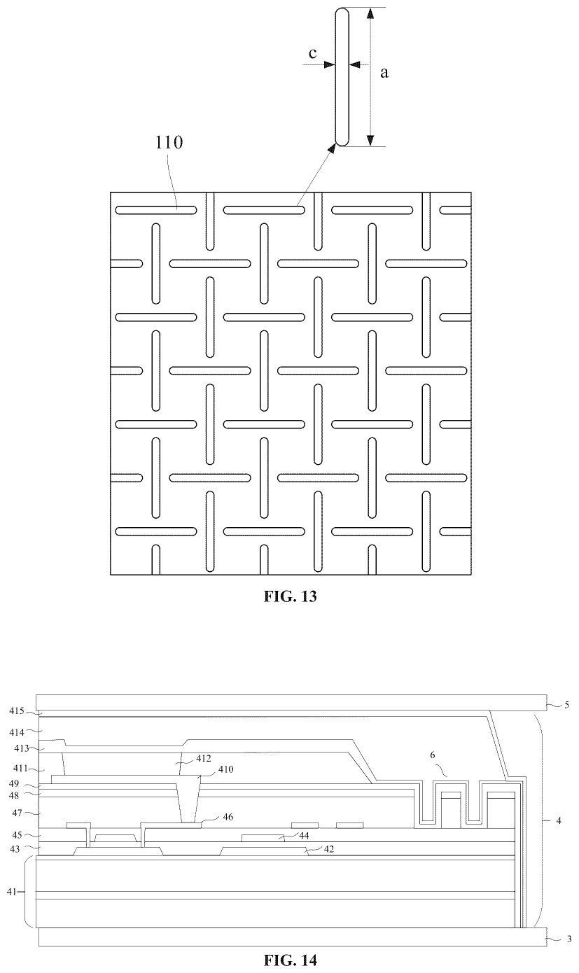

FIG. 13 is a schematic diagram of dimensioning of a strip-shaped hole according to some embodiments of the present disclosure. Referring to FIG. 13, a length a of the strip-shaped hole ranges from 170 μm to 600 μm, a width c of the strip-shaped hole ranges from 4 μm to 50 μm, and a minimum distance d between adjacent strip-shaped holes ranges from 80 μm to 200 μm.

Exemplarily, the length a of the strip-shaped hole is 400 μm, the width c of the strip-shaped hole is 30 μm, and the minimum distance d between adjacent strip-shaped holes is 150 μm.

In the display region 2, the length of the first strip-shaped body portion 1111 or the second strip-shaped body portion 1121 ranges from 250 μm to 800 μm.

The length of the trapezoidal portion 1112 or the strip-shaped branch portion 1122 ranges from 100 μm to 250 μm.

The width of the first strip-shaped body portion 1111 and the trapezoidal portion 1112, or the second strip-shaped body portion 1121 and the strip-shaped branch portion 1122 ranges from 4 μm to 50 μm.

The minimum distance between adjacent I-shaped holes ranges from 40 μm to 100 μm.

Exemplarily, the length of the first strip-shaped body portion 1111 or the second strip-shaped body portion 1121 is 500 μm.

The length of the trapezoidal portion 1112 or the strip-shaped branch portion 1122 is 180 μm.

The width of the first strip-shaped body portion 1111 and the trapezoidal portion 1112, or the second strip-shaped body portion 1121 and the strip-shaped branch portion 1122 is 30 μm. The minimum distance between adjacent I-shaped holes is 70 μm.

Referring to FIG. 11 again, in the display region 2, a bridge region 113 and an island region 114 are also provided. The wiring is arranged in the bridge region 113, and a light-emitting structure is arranged in the island region 114.

Exemplarily, an area of the island region 114 disposed in the display region 2 is less than that of the island region 114 disposed in the peripheral region 1, and a width of the bridge region 113 disposed in the display region 2 is less than that of the bridge region 113 disposed in the peripheral region 1.

The bridge region 113 is in the shape of a strip, and the width of the bridge region 113 is a width of the strip.

FIG. 14 is a schematic diagram of layers of a flexible display substrate according to some embodiments of the present disclosure. Referring to FIG. 14, the flexible display substrate includes:

a flexible substrate 3, a display functional film layer 4, and a cover plate 5 disposed sequentially on the flexible substrate 3, wherein projections of edges of the flexible substrate 3 and the cover plate 5 in a plane that a surface of the display functional film layer 4 is within are outside the surface of the display functional film layer 4.

The cover plate 5 is made of an optically clear adhesive (OCA), e.g., a positive photoresist or a negative photoresist.

In some practices, the outermost side of the display functional film layer of the flexible display substrate is provided with a heat-affected region and a heat-affected dyke to eliminate the heat impact of laser cutting. In the embodiments of the present disclosure, the projections of the edges of the flexible substrate 3 and the cover plate 5 in the plane that the surface of the display functional film layer 4 is within are outside the surface of the display functional film layer 4, i.e., the flexible substrate 3 and the cover plate 5 are outwardly expanded with respect to the display functional film layer 4, and the original heat-affected area and the heat-affected dyke are replaced by the outwardly expanded flexible substrate 3 and cover plate 5, which simplifies the structural complexity of the display functional film layer and facilitates the fabrication of the display functional film layer. The outermost structure of the display functional film layer is a waterproof dyke without the heat-affected area and the heat-affected dyke (the structure in some practices has both the waterproof dyke and the heat-affected dyke).

Referring to FIG. 14 again, the display functional film layer 4 includes: a buffer layer 41, an active layer 42, a gate insulating layer 43, a gate layer 44, a source-drain insulating layer 45, a source-drain layer 46, a first planarization layer 47, a spacer layer 48, a first cover plate 49, an anode layer 410, a pixel-defining layer 411, a light-emitting layer 412, a cathode layer 413, a second planarization layer 414, and a second cover plate 415.

The first planarization layer 47, the spacer layer 48, the first cover plate 49 and the cathode layer 413 are formed in the peripheral region with the aforementioned waterproof dyke 6 for water and oxygen corrosion protection.

Exemplarily, the buffer layer 41 is composed of a plurality of sub-layers, such as the plurality of sub-layers included in FIG. 13, for example including two inorganic sub-layers and two organic sub-layers. It is to be noted that the aforementioned flexible substrate 3 also serves as a buffer, such that the flexible substrate 3 and the buffer layer 41 together form the buffer layer (Buffer, BF).

Exemplarily, the active layer 42 is a Low Temperature Poly-Silicon (LTPS) layer. The LTPS has a high mobility and good stability, which meets the requirements of high-resolution displays.

Exemplarily, the gate insulating layer 43 is an inorganic insulating layer, such as a silicon nitride (SiN) insulating layer, or an organic insulating layer, such as an annular resin insulating layer. The silicon nitride and the annular resin are well insulated to ensure the insulation of the gate insulating layer 43.

Exemplarily, the source-drain insulating layer 45 is the inorganic insulating layer, such as the silicon nitride insulating layer, or the organic insulating layer, such as the annular resin insulating layer. The silicon nitride and the annular resin are well insulated to ensure the insulation of the source-drain insulating layer 45.

Exemplarily, the gate layer 44 is a metal layer or an indium tin oxide layer, such that the stability of the electrical signal transmission of the gate layer 44 is ensured.

Exemplarily, the source-drain layer 46 is a metal layer or an indium tin oxide layer, such that the stability of the source-drain layer 46 electrical signal transmission is ensured.

Exemplarily, the first planarization layer 47 and the second planarization layer 414 are resin layers, with the resin having insulating properties that ensure the insulating properties of the second planarization layer 414.

Exemplarily, the spacer layer 48 is an organic or inorganic insulating spacer layer.

Exemplarily, the anode layer 410 is a metal layer. The cathode layer 413 is an indium tin oxide film layer.

Exemplarily, the pixel defining-layer 411 is a hydrophobic material layer, such as a fluorinated polyimide or fluorinated polymethylmethacrylate layer.

Exemplarily, the light-emitting layer 412 includes a hole transport layer, an organic light-emitting layer, and an electron transport layer, which are stacked.

Exemplarily, the first cover plate 49 and the second cover plate 415 are encapsulated by a Thin-Film Encapsulation (TFE) method to ensure the encapsulation effect.

The embodiments of the present disclosure also provide a display panel including the flexible display substrate as described in any one of FIGS. 1 to 14.

In the embodiments of the present disclosure, by providing a notch in the edge of the second region in the middle of the corner region of the peripheral region of the flexible display substrate, when the peripheral region of the flexible display substrate is downwardly stretched to be attached to the bezel of the terminal to be mounted, the notch is able to absorb shrinkage deformation during the attachment, and deformation amounts in the corner region are counteracted by the notch, thereby addressing the problem of causing corrugations during attachment in the corner region and improving the attachment effect.

The embodiments of the present disclosure also provide a display device including the display panel as described above.

The display device in the embodiments of the present disclosure is any product or component with the display function, such as a mobile phone, a tablet computer, a television, a display, a notebook computer, a digital photo frame, a navigator, or the like.

In the embodiments of the present disclosure, by providing a notch in the edge of the second region in the middle of the corner region of the peripheral region of the flexible display substrate, when the peripheral region of the flexible display substrate is downwardly stretched to be attached to the bezel of the terminal to be mounted, the notch is able to absorb shrinkage deformation during attachment, and deformation amounts in the corner region are counteracted by the notch, thereby addressing the problem of causing corrugations during attachment in the corner region and improving the attachment effect.

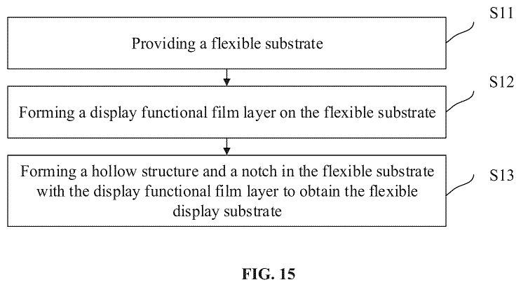

FIG. 15 is a flowchart of a method for manufacturing a flexible display substrate according to some embodiments of the present disclosure. As illustrated in FIG. 15, the method includes the following steps.

In S11, a flexible substrate is provided.

In S12, a display functional film layer is formed on the flexible substrate.

The display functional film layer at least includes a light-emitting element, a peripheral circuit and a wiring.

In S13, a hollow structure and a notch are formed in the flexible substrate with the display functional film layer to obtain the flexible display substrate.

The flexible display substrate includes a display region and a peripheral region, the peripheral region is disposed around the display region, the display region and the peripheral region have a hollow structure and a notch design, see any one of FIGS. 1 to 13.

In the embodiments of the present disclosure, by providing a notch in the edge of the second region in the middle of the corner region of the peripheral region of the flexible display substrate, when the peripheral region of the flexible display substrate is downwardly stretched to be attached to the bezel of the terminal to be mounted, the notch is able to absorb shrinkage deformation during attachment and deformation amounts in the corner region are counteracted by the notch, thereby addressing the problem of causing corrugations during attachment in the corner region and improving the attachment effect.

Exemplarily, the hollow structure and the notch are formed using a patterning process. The hollow structure and the notch run through the display functional film layer and the flexible substrate.

In some embodiments, prior to S13, the method further includes: forming a cover plate.

The cover plate covers the display functional film layer to protect the display functional film layer. Exemplarily, the cover plate is made of an optical clear adhesive.

Described above are merely optional embodiments of the present disclosure, and are not intended to limit the present disclosure. Within the spirit and principles of the present disclosure, any modifications, equivalent substitutions, improvements, and the like are within the protection scope of the present disclosure.

1. A flexible display substrate, comprising: a peripheral region and a display region, the peripheral region surrounding the display region; wherein
the peripheral region has a plurality of corner regions, at least one of the corner regions comprising two first regions and a second region disposed between the two first regions; and
the first region has a hollow structure, and the second region has at least one notch disposed in an edge of the flexible display substrate.

2. The flexible display substrate according to claim 1, wherein the notch is a semi-elliptical notch, a semi-circular notch, a rectangular notch, a trapezoidal notch, or an arcuate notch.

3. The flexible display substrate according to claim 2, wherein a long axis of the notch is intersected with the edge in which the notch is disposed at one intersection point.

4. The flexible display substrate according to claim 3, wherein the notch is the semi-elliptical notch.

5. The flexible display substrate according to claim 4, wherein a long axis of the semi-elliptical notch ranges from 200 μm to 600 μm;
a short axis of the semi-elliptical notch ranges from 40 μm to 80 μm; and
in the case that the second region has a plurality of the semi-elliptical notches, a minimum distance between adjacent two of the semi-elliptical notches ranges from 5 μm to 40 μm.

6. The flexible display substrate according to claim 1, wherein the second region comprises:
two first sub-regions and one second sub-region, wherein the second sub-region is disposed between the two first sub-regions, the first sub-region and the second sub-region are arranged in an extension direction along the edge of the flexible display substrate, and the notch is disposed in each of the two first sub-regions.

7. The flexible display substrate according to claim 6, wherein the second sub-region is disposed in a center of the corner region.

8. The flexible display substrate according to claim 6, wherein the second sub-region is a non-hollow region.

9. The flexible display substrate according to claim 8, further comprising: a peripheral circuit, wherein at least a portion of the peripheral circuit is disposed within the second region.

10. The flexible display substrate according to claim 9, wherein the peripheral circuit comprises a GOA circuit, wherein the GOA circuit is disposed in the second sub-region.

11. The flexible display substrate according to claim 1, wherein the hollow structure comprises a plurality of I-shaped holes, the plurality of I-shaped holes comprising at least one of a first through-hole and a second through-hole; wherein
the first through-hole comprises a first strip-shaped body portion and two trapezoidal portions, wherein the two trapezoidal portions are respectively disposed at both ends of the first strip-shaped body portion and an upper base of the trapezoidal portion is connected to the first strip-shaped body portion; and
the second through-hole comprises a second strip-shaped body portion and two strip-shaped branch portions, wherein the two strip-shaped branch portions are respectively disposed at both ends of the second strip-shaped body portion and a middle of each of the two strip-shaped branch portions is connected to the second strip-shaped body portion.

12. The flexible display substrate according to claim 11, wherein
a length of the first strip-shaped body portion or the second strip-shaped body portion ranges from 170 μm to 600 μm;
a length of the trapezoidal portion or each of the two strip-shaped branch portions ranges from 60 μm to 160 μm;
widths of the first strip-shaped body portion and the trapezoidal portion or the second strip-shaped body portion and each of the two strip-shaped branch portions both range from 4 μm to 50 μm; and
a minimum distance between adjacent two of the I-shaped holes ranges from 80 μm to 200 μm.

13. The flexible display substrate according to claim 11, wherein a gap between adjacent two of the I-shaped holes is a bridge region and a gap enclosed by adjacent four of the I-shaped holes is an island region;
wherein wirings are arranged in the bridge region and peripheral circuits are arranged in the island region.

14. The flexible display substrate according to claim 1, wherein the display region has the hollow structure, and an area of the hollow structure in the display region per unit area is greater than an area of the hollow structure in the peripheral region.

15. The flexible display substrate according to claim 14, wherein
the hollow structure of the display region comprises the plurality of I-shaped holes, and the plurality of I-shaped holes comprise at least one of the first through-hole and the second through-hole;
the first through-hole comprises the first strip-shaped body portion and the two trapezoidal portions, the two trapezoidal portions are respectively disposed at the two ends of the first strip-shaped body portion, and an upper base of the trapezoidal portion is connected to the first strip-shaped body portion; and
the second through-hole comprises the second strip-shaped body portion and the two strip-shaped branch portions, the two strip-shaped branch portions are respectively disposed at the two ends of the second strip-shaped body portion, and the middle of each of the two strip-shaped branch portions is connected to the second strip-shaped body portion.

16. The flexible display substrate according to claim 15, wherein the length of the first strip-shaped body portion or the second strip-shaped body portion disposed in the display region is greater than the length of the first strip-shaped body portion or the second strip-shaped body portion disposed in the peripheral region.

17. (canceled)

18. The flexible display substrate according to claim 15, wherein the bridge region and the island region are disposed between the I-shaped holes disposed in the display region; wherein an area of the island region disposed in the display region is less than an area of the island region disposed in the peripheral region, and a width of the bridge region disposed in the display region is less than a width of the bridge region disposed in the peripheral region.

19. The flexible display substrate according to claim 1, further comprising:
a flexible substrate, and a display functional film layer and a cover plate that are sequentially disposed on the flexible substrate, wherein a projection of edges of the flexible substrate and the cover plate in a plane that a surface of the display functional film layer is within is outside a surface of the display functional film layer.

20. A display panel, comprising: a flexible display substrate; wherein
the flexible display substrate comprises: a peripheral region and a display region, the peripheral region surrounding the display region; wherein
the peripheral region has a plurality of corner regions, at least one of the corner regions comprising two first regions and a second region disposed between the two first regions; and
the first region has a hollow structure, and the second region has at least one notch disposed in an edge of the flexible display substrate.

21. A display device, comprising: a display panel comprising a flexible display substrate; wherein
the flexible display substrate comprises: a peripheral region and a display region, the peripheral region surrounding the display region; wherein
the peripheral region has a plurality of corner regions, at least one of the corner regions comprising two first regions and a second region disposed between the two first regions; and
the first region has a hollow structure, and the second region has at least one notch disposed in an edge of the flexible display substrate.
